(19) United States
(12) Patent Application Publication
(10) Pub. No.: US 2010/0059244 A1
(43) Pub. Date: Mar. 11, 2010

(54) Microstructure Apparatus and Method for Manufacturing Microstructure Apparatus

(75) Inventor: Itaru Ishii, Kirishima-shi (JP)

Correspondence Address: HOGAN & HARTSON L.L.P., 1999 AVENUE OF THE STARS, SUITE 1400, LOS ANGELES, CA, 90067, US

(73) Assignee: KYOCERA CORPORATION, Kyoto-shi, Kyoto (JP)

(21) Appl. No.: 12/530,182

(22) PCT Filed: Mar. 5, 2008
(86) PCT No.: PCT/JP2008/053976

§ 371 Date: Sep. 4, 2009

(30) Foreign Application Priority Data
Mar. 5, 2007 (JP) 2007-054569
Sep. 28, 2007 (JP) 2007-255338

(51) Int. Cl. H05K 5/06

(52) U.S. Cl. 174/50.5

(57) ABSTRACT

The invention relates to a microstructure apparatus. A microstructure apparatus according to one of the invention includes a first substrate having a surface on which a microstructure is disposed; a second substrate having a surface opposing the microstructure; and a sealing member that bonds the opposing surfaces of the first substrate and the second substrate and that encloses and seals the microstructure. The sealing member includes a brazing metal containing a filler.

### TECHNICAL FIELD

The present invention relates to a microstructure apparatus comprising a microstructure, such as a surface acoustic wave (SAW) element, a microelectromechanical system (MEMS), or the like, which is sealed between two substrates, and a method for manufacturing a microstructure apparatus.

### BACKGROUND ART

Recently, an electronic component has been attracting attention and has been developed for practical use, in which an extremely small electromechanical system, a so-called MEMS (micro electromechanical system), is formed on the surface of a semiconductor substrate made of a silicon wafer or the like by the application of processing techniques for forming fine wiring of semiconductor integrated circuit elements and the like.

This sort of MEMS has to be sealed from the outside in order to prevent contamination, and various materials, such as resin and glass, are used as sealing members. In particular, a brazing metal, more specifically, a solder having a melting point of 450 degrees or lower is suitable as a sealing member, due to the excellent airtightness and ability to seal an MEMS in a temperature range where the MEMS is less affected (for example, Japanese Unexamined Patent Publication JP-A 2005-251898). Furthermore, due to recent lead-free trends, for example, a SnAgCu (tin silver-copper)-based solder is becoming used as a sealing member.

Conversely, in recent MEMS development trends, a so-called wafer-level packaging technique is commonly used in which a plurality of microstructures are formed on a silicon wafer or a glass wafer, and the MEMS structures are sealed before the wafer is cut into chips. Furthermore, in the case where a water on which the MEMS is formed and a sealing substrate are bonded using such a wafer-level packaging technique, the bonding is commonly performed by thermocompression bonding. In bonding by thermocompression bonding, a wafer and a sealing substrate can be bonded while warpage or waviness thereof is corrected.

However, in the case where the wafer and the sealing substrate are thermocompression-bonded while an SnAgCu-based solder interposed therebetween, the SnAgCu-based solder is heated to a temperature of the outoctic point or higher, and, thus, the solder is melted. Furthermore, the melted solder spreads due to the load.

### DISCLOSURE OF INVENTION

The invention is devised to solve the above-described problem, and it is an object thereof to provide a microstructure apparatus in which even if a load is applied during manufacturing process with a brazing metal used as a sealing member of a microstructure, crush of the brazing metal can be suppressed and the microstructure can be hermetically sealed, and a method for manufacturing the microstructure apparatus.

A microstructure apparatus according to one of the invention comprises a first substrate having a surface on which a microstructure is disposed; a second substrate having a surface opposing the microstructure; and a sealing member that bonds the opposing surfaces of the first substrate and the second substrate and that encloses and seals the microstructure. The sealing member comprises a brazing metal containing a filler.

Furthermore, a method for manufacturing a microstructure apparatus according to one of the invention comprises a first substrate having a surface on which a microstructure is disposed, a second substrate having a surface opposing the microstructure, and a sealing member that bonds the opposing surfaces of the first substrate and the second substrate and that encloses and seals the microstructure. The manufacturing method comprises an applying step of applying a paste containing brazing metal balls and metal balls to the surface of the second substrate; a heating step of heating the paste to a temperature equal to or higher than the melting point of the brazing metal balls, equal to or higher than a temperature at which a compound made of materials that respectively form the brazing metal balls and the metal balls is produced, and lower than a temperature at which the metal balls are connected to each other with the compound; and a thermocompression bonding step of thermocompression-bonding the first substrate and the second substrate by bringing the surface of the first substrate into contact with the paste, and connecting the first substrate and the second substrate with the compound and the metal balls.

Furthermore, a method for manufacturing a microstructure apparatus according to one of the invention comprises a first substrate having a surface on which a microstructure is disposed, a second substrate having a surface opposing the microstructure, and a sealing member that bonds the opposing surfaces of the first substrate and the second substrate and that encloses and seals the microstructure. The manufacturing method comprises a providing step of providing the first substrate and the second substrate, a conductor pattern being disposed on at least one of the surface of the first substrate and the surface of the second substrate that are to oppose each other; an applying a step of applying a paste containing brazing metal balls and metal balls to the surface of the second substrate; a heating step of heating the paste to a temperature equal to or higher than the melting point of the brazing metal balls, equal to or higher than a temperature at which a material forming the conductor pattern is diffused into the paste, and lower than a temperature at which the metal balls are coupled via a compound made of materials that respectively form the brazing metal balls, the metal balls, and the conductor pattern; and a thermocompression bonding step of thermocompression-bonding the first substrate and the second substrate by bringing the surface of the first substrate into contact with the paste, and connecting the first substrate and the second substrate to each other with the compound and the metal balls.

### BRIEF DESCRIPTION OF DRAWINGS

Other and further objects, features, and advantages of the invention will be more explicit from the following detailed description taken with reference to the drawings wherein:

FIG. 1 is a cross-sectional view showing a configuration example of a microstructure apparatus according to a first embodiment of the invention, and is a cross-sectional view of the plan view shown in FIG. 2 taken along line A-A;

FIG. 2 is a plan view of the microstructure apparatus shown in FIG. 1;

FIGS. 3A to 3D are views showing an example of a method for manufacturing the microstructure apparatus according to the first embodiment of the invention in processing order; and

FIGS. 4A to 4D are views showing an example of a method for manufacturing the microstructure apparatus according to a second embodiment of the invention in processing order.

### BEST MODE FOR CARRYING OUT THE INVENTION

Now referring to the drawings, preferred embodiments according to a microstructure apparatus of the invention are described below.

### First Embodiment

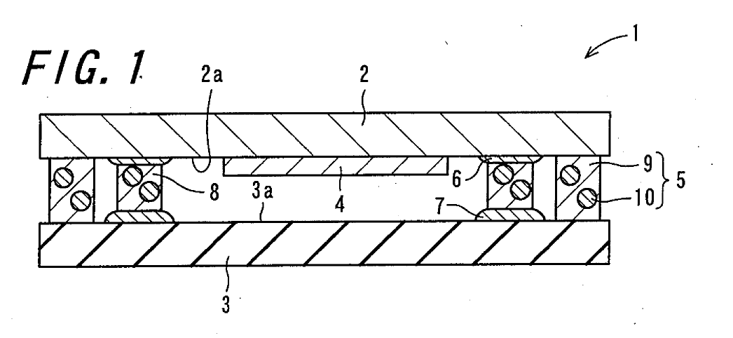

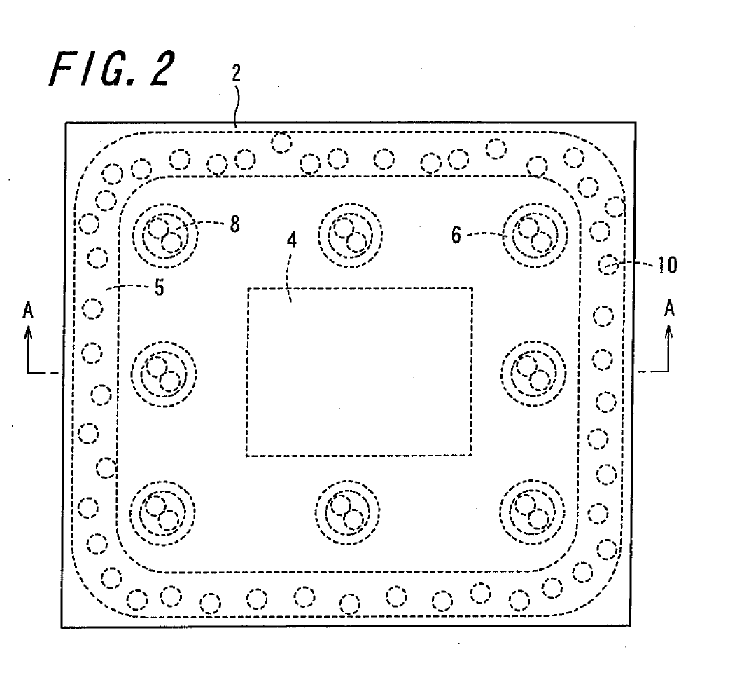

As shown in FIGS. 1 and 2, a microstructure apparatus 1 according to this embodiment includes a first substrate 2 and a second substrate 3. A microstructure 4 is disposed on a surface 2a of the first substrate. The first substrate 2 and the second substrate 3 are arranged so that the surface 2a of the first substrate and a surface 3a of the second substrate 3 oppose each other. Furthermore, the microstructure apparatus 1 includes a sealing member 5 that bonds the opposing surfaces 2a and 3a of the first substrate 2 and the second substrate 3 and that encloses and seals the microstructure 4. Furthermore, the microstructure apparatus 1 includes a conductive member 8 that electrically connects an electrode 6 disposed on the surface 2a of the first substrate 2 and a wiring conductor 7 disposed on the surface 3a of the second substrate 3. Here, the sealing member 5 is formed by adding filler 10 to a solder 9.

The microstructure 4 is a device made of, for example, a crystal, a semiconductor, or the like. Examples of a device that particularly has to be sealed include a SAW element, a crystal oscillator, and an MEMS. Illustrating an MEMS as an example, an MEMS has the function of, for example, optical switches, display devices, various sensors such as acceleration sensors or pressure sensors, electrical switches, inductors, capacitors, resonators, antennas, microrelays, magnetic heads for hard disks, microphones, biosensors, DNA chips, microreactors, printheads, or the like. These MEMSs are components produced by so-called micromachining methods based on semiconductor fine processing techniques, and have a size of 10 micrometers to several hundreds of micrometers per an element.

The first substrate 2 is made of a semiconductor of silicon, gallium arsenide, or the like, and the device is formed by repeating film formation and etching on the surface. Furthermore, in the case where an MEMS is formed, the first substrate 2 is not limited to a semiconductor, and may be a glass substrate of Pyrex (registered trademark) glass or the like.

The electrode 6 is formed on the first substrate 2, mainly using a thin film-forming method, such as a sputtering method, a chemical vapor deposition (CVD) method, or the like. Examples of the produced thin film include titanium (Ti), tungsten (W), gold (Au), nickel (Ni), chromium (Cr), palladium (Pd), platinum (Pt), and/or the like, and the thin film may be multi-layered thin films. Furthermore, in the case of multi-layered thin films, it is desirable that the outermost layer is a metal such as Au having a good wettability with Sn.

The second substrate 3 is made of a ceramic material, such as an aluminum oxide-based sintered compact, an aluminum nitride-based sintered compact, a mullite baaed sintered compact, a silicon carbide-based sintered compact, a silicon nitride-based sintered compact, or glass ceramic sintered compact.

For example, in the case where the second substrate 3 is made of an aluminum oxide-based sintered compact, the second substrate 3 is formed by layering and firing green sheets that are obtained by forming raw powders such as aluminum oxide and a glass powder on a sheet. The material of the second substrate 3 is not limited to an aluminum oxide-based sintered compact, and a suitable material is preferably selected according to the application purpose, the characteristics of the microstructure 4 that is to be hermetically sealed, and the like.

For example, since the second substrate 3 is mechanically bonded to the first substrate 2 with the sealing member 5, the second substrate 3 is preferably made of a material having a coefficient of thermal expansion not so much different from that of the first substrate 2, in order to increase the reliability of bonding with the first substrate 2, that is, the airtightness of the sealing of the microstructure 4. Examples of this material include a mullite based sintered compact, or a glass ceramic sintered compact of an aluminum oxide-borosilicate glass-based material whose coefficient of thermal expansion has been approximated to that of the first substrate 2 by adjusting the type and amount of glass component added.

The wiring conductor 7 is made of a metal material, such as copper, silver, gold, palladium, tungsten, molybdenum, or manganese. In the case where the second substrate 3 is made of ceramic and the wiring conductor 7 is made of copper using a thick film method, the wiring conductor 7 is formed, for example, by screen-printing a metal paste, which is obtained by adding and mixing an appropriate organic blinder and solvent with a copper powder and a glass powder, onto green sheets that are to be the second substrate 3, and then firing the screen printed metal paste and the green sheets.

Furthermore, a glass ceramic sintered compact obtained by sintering an aluminum oxide filler and glass such as borosilicate glass is preferable as the material of the second substrate 3 that processes high frequency signals, because a wiring conductor can be made of copper or silver having a small electrical resistance, and a electrical signal delay can be suppressed due to a low relative permittivity.

The shape of the second substrate 3 is not particularly limited, as long as the second substrate 3 can function as a cover member for sealing the microstructure 4 and function as a base member for forming a conductor pattern or the like.

Furthermore, a recess portion that internally accommodates the microstructure 4 may be formed on the upper face of the second substrate 3. In the case where the microstructure 4 is partially accommodated in the recess portion, the height of the sealing member 5 for enclosing the microstructure 4 can be reduced, and, thus, the height of the microstructure apparatus 1 can be advantageously reduced. Furthermore, it is desirable that the external size of the first substrate 2 and the second substrate 3 in a plan view thereof is set to have an approximately several millimeters on a side in case that the substrates are in the shape of rectangles, in order to reduce the size of the microstructure apparatus 1.

The sealing member 5 is a frame-shaped member, and interposed between the first substrate 2 and the second substrate 3 so that the internal space enclosed by the sealing member 5 accommodates the microstructure 4. The sealing member 5 functions as a side wall for hermetically sealing the microstructure 4 in the internal space. In this case, if the upper face of the second substrate 3 is flat, the thickness of the sealing member 5 corresponds to the thickness of the sealed space for the microstructure 4, and, thus, the sealed space for the microstructure 4 can be formed with a simple structure.

In the microstructure apparatus 1, the sealing member 5 is made of the solder 9 containing the filler 10. The solder 9 is, for example, an SnAg-based or SnAgCu-based solder. In order to secure a higher reliability, it is desirable that the height of the sealing member 5 is 50 μm or more. The solder 9 has an elastic modulus smaller than that of ceramic or a semiconductor, and, thus, the solder 9 is significantly deformed, and has a property that does not internally accumulate strain. This property becomes more significant as the amount of solder becomes larger, and, thus, the effect of alleviating strain becomes significant when the height of the sealing member 5 is 50 μm or more.

Furthermore, in order to lower the melting point of the solder 9, other materials may be added to the solder 9. For example, in the case where the solder 9 is an SnAgCu-based solder, the melting point can be lowered by adding a trace component, such as bismuth, zinc, or palladium.

The filler 10 is made of metal spheres (metal balls) of, for example, copper, silver, nickel, or the like. The material of the filler 10 may be any metal, as long as the wettability with tin (Sn) is good, an intermetallic compound with Sn is formed, and this intermetallic compound can provide the sealing member 5 with thermal resistance and a low elastic modulus. For example, the filler 10 may be any metal, such as gold, as long as an intermetallic compound (an AuSn compound) with Sn is formed, and the melting point of this intermetallic compound is higher than that of Sn.

Furthermore, the filler 10 also may be resin balls. In the case where the filler 10 is resin balls, an acrylic-based resin material is commonly used. In particular, in a case where the high-frequency characteristics of the solder portion affect the microstructure 4, a Teflon (registered trademark)-based resin material is preferably used. In view of the wettability with the solder, the surface of the resin balls may be coated with a metal, by a technique such as plating. The resin material is not limited to the above-described materials, and may be other materials, as long as a sufficient mounting reliability is obtained.

In the case where the filler 10 is metal balls, the electrical conductivity of the solder material can be increased, and, thus, the sealing member 5 can be used as a conductor that supplies a reference potential, for example, as a stable ground conductor. Furthermore, the sealing member 5 made of a solder containing the filler 10 has a high thermal conductivity, and, thus, the sealing member 5 is an effective means for sealing the microstructure 4 that generates a large amount of heat.

Furthermore, in the case where the filler 10 is resin balls or plastic balls, the Young's modulus of the filler 10 can be lowered. When the temperature cycle affects the solder 9, the filler 10 is freely deformed, and, thus, the mounting reliability is improved.

Examples of the solder 9 include SnCu, AuSn, and the like. Furthermore, in the description above, the solder 9 containing the filler 10 was shown as an example of the sealing member 5, but the solder 9 also may be a brazing metal having a melting point of higher than 450 degrees. Here, a solder is one brazing metal, and refers to a brazing metal having a melting point of 450 degrees or lower.

In order to improve the wettability with the sealing member 5, a pad is formed on the surface 2a of the first substrate 2 and the surface 3a of the second substrate 3. This pad may be, for example, a film made of Cu or Ag formed by a thick film method.

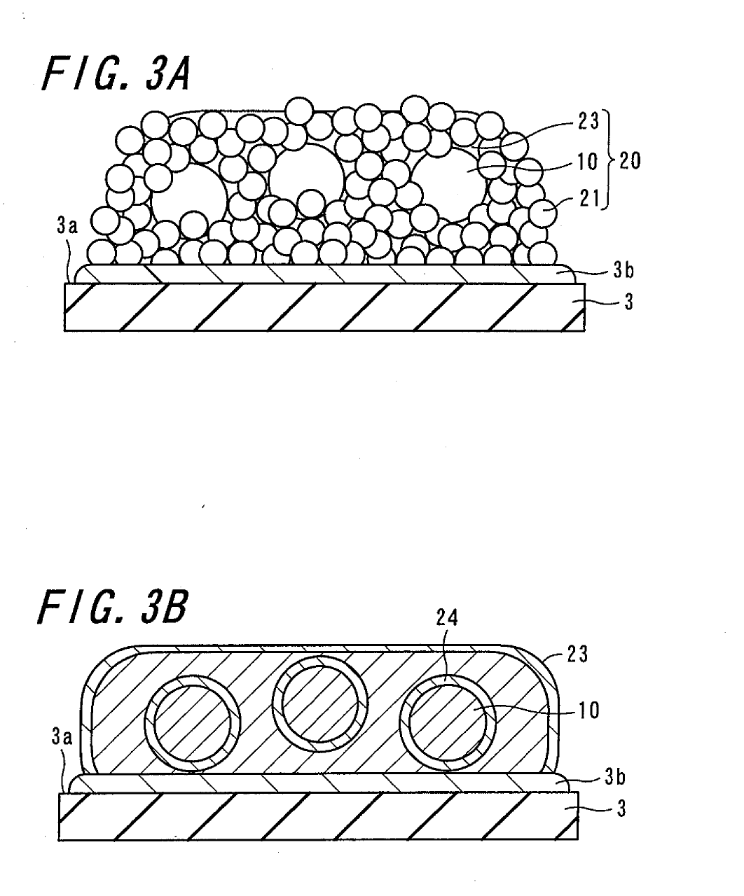

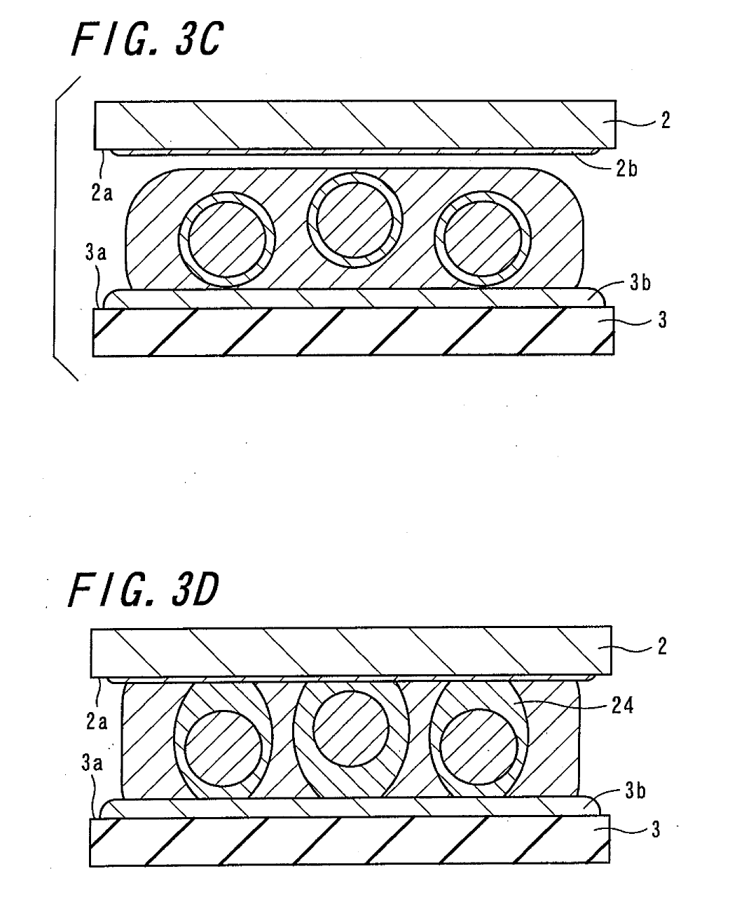

Next, a method for manufacturing the microstructure apparatus 1 is described with reference to FIGS. 3A to 3D. FIGS. 3A to 3D are views for illustrating a method for forming the sealing member b in the manufacturing processing of the microstructure apparatus 1 according to this embodiment. In FIGS. 3A to 3D, the same portions as in FIG. 1 are denoted by the same reference numerals.

First, as shown in FIG. 3A, a paste 20 that is to be the sealing member 5 is applied to the second substrate 3. The paste 20 includes balls made of an Sn-based solder (hereinafter, simply referred to as “solder balls”) 21, the filler 10, and a flux 23, and is formed on the second substrate 3 by a technique such as screen printing. Typically, the particle size of the solder balls 21 is approximately 5 to 30 μm. The flux 23 fills a space between the solder balls 21 and particles of the filler 10. The flux 23 is made of an organic material such as a halogen-based organic component, which has the ability to remove a metal oxide film, and also functions as a binder in the case where the solder balls 21 and the filler 10 are mixed. The amount of flux 23 contained is typically approximately 9 to 13% by weight to that of the entire paste 20, in view of the ability to remove an oxide film, the viscosity and the rheological properties of the paste 20 in which the filler 10 is mixed, and the like. In order to secure the wettability with the solder, a pad 3b that forms a conductor pattern made of a metal, such as Cu or Ag (Cu in this embodiment), is preferably disposed on the second substrate 3. Here, in the case where the pad 3b is made of Cu as in this embodiment, the ratio of the total weight of the filler 10 and the pad 3b to the weight of balls made of an Sn-based solder is preferably 1/10 or more and ½ or less. This weight ratio can be obtained by shaving the cross section of the sealing member 5, mapping the element distribution of the cross section using a technique, such as wavelength dispersive EPMA (electro probe micro analysis), and performing measurement in terms of the area of the mapped elements.

Next, as shown in FIG. 3B, a solder precoat is formed on the second substrate 3 by performing heat treatment, and melting the solder balls 21. In this processing, a solder precoat in which the paste 20 that is to be the sealing member 5 has a certain level of flowability is produced, so that bonding of the first substrate 2 to the solder 9, which is performed in the following processing, is easily performed. In the case where the solder precoat is to be formed, the paste 20 applied to the second substrate 3 is subjected to heat treatment inside a reflow apparatus or the like, and the solder balls 21 are melted. At this stage, the solder balls 21 and the flux 23 are melted, and, in some cases, an intermetallic compound 24 of the solder balls 21 and the filler 10 is formed. This intermetallic compound is a CuSn compound made of Cu₆Sn₅. Furthermore, the flux 23 is disposed on the surface of the solder precoat so as to cover the melted solder.

In particular, in the case where the solder balls 21 are made of an SnAgCu-based solder and the filler 10 is made of copper balls, it is desirable that the atmosphere inside the reflow apparatus is a nitrogen atmosphere in order to suppress the formation of metal oxides. Furthermore, in order to suppress the formation of voids inside the solder precoat due to the remaining flux 23, the temperature may be maintained at not lower than the flushing point at which evaporation of the flux 23 starts, and melting may be performed at not lower than the melting point of the solder balls 21 after the flux 23 is removed from the solder precoat.

In this processing, the reflow temperature is increased only up to a certain level of temperature. This is in order to suppress loss of flowability of the solder caused by connection of the metal balls 10 which is due to too grown intermetallic compound layer 24 around the filler 10, which is made of an intermetallic compound of the solder balls 21 and the filler 10. Regarding the combination of a SnAgCu-based solder and the filler 10 made of Cu, it is confirmed that formation of an SnCu intermetallic compound is suppressed, generally, in the case where the reflow temperature is lower than 250° C.

Preferably, the flux is washed after reflow processing, and a flux residue on the second substrate 3 is removed. Examples of the washing agent include a surfactant, a washing agent belonging to a fourth-class petroleum as defined in Japanese regulatory laws, and an alcohol-based washing agent. In the case where the flux is washed in this manner, contamination inside the microstructure apparatus 1 can be suppressed, and, thus, a microstructure apparatus 1 having a better quality and a better performance can be provided. In particular, in the case where the microstructure 4 is an MEMS, this effect is significant, because contamination of the operating portion can be suppressed.

Next, FIG. 3C shows processing that prepares the first substrate 2. The first substrate 2 is a substrate mainly made of silicon on which the microstructure 4, such as an MEMS, is mounted. The three-dimensional structure of the MEMS is formed by the application of silicon fine wiring techniques. More specifically, a thin film of a conductor made of Cu, Au, aluminum (Al), or the like is formed as a wiring conductor, and then silicon is etched using a chemical or physical technique. Examples of a commonly used chemical technique include a wet etching technique using hydrofluoric acid (HF) and the like. Examples of a physical etching technique include techniques such as D-RIE (deep reactive ion etching). Here, in order to secure the wettability, a pad 2b that forms a conductor pattern made of a metal is preferably disposed on the surface of the first substrate 2 that is brought into contact with the solder precoat.

Next, as shown in FIG. 3D, the first substrate 2 and the second substrate 3 are thermocompression bonded. The pressure range at thermocompression bonding is preferably approximately 0.1 to 10 MPa. Furthermore, the temperature range is set to a temperature higher than that when forming the solder precoat shown in FIG. 3B, and typically, the temperature range of 250° C. or higher is desirable. In this processing, the intermetallic compound layer 24 grows sufficiently. and the first substrate 2 and the second substrate 3 are firmly bonded with the intermetallic compound layer 24. That is to say, a CuSn compound layer made of Cu₆Sn₅ is present on at least one of the boundary between the first substrate 2 and the sealing member 5 and the boundary between the second substrate 3 and the sealing member b.

If the temperature range is 350° C. or lower, a decrease in mounting yield due to problems such as outgassing from the solder material, re-melting of the intermetallic compound layer 24 or the like can be suppressed.

According to the microstructure apparatus 1 of this embodiment, since the sealing member 5 is made of the solder 9 containing the filler 10, crush of the solder 9 can be suppressed even if a load is applied during manufacture. Thus, when the sealing member 5 is formed by thermocompression bonding, the filler 10 suppresses the flowability of the solder 9. Accordingly, even if a pressure is applied to the solder 9, crush of the material of the solder 9 can be suppressed. Accordingly, the height of the sealing member 5 is secured, and the hermetic seal reliability can be secured.

Furthermore, in the above-described manufacturing method, even in the case where the solder balls 21 are heated to a temperature higher than the melting point, the flowability is suppressed due to the filler 10 added. The solder precoat maintains a certain level of viscosity within a temperature equal to or higher than the melting point of the solder balls 21 and lower than a temperature at which the metal balls 10 are connected to each other with a compound made of the solder balls 21 and the metal balls 10. The first substrate 2 can be bonded to the solder 9 in this solder precoat state, and, thus, the degree of adhesion between the first substrate and the solder 9 is improved. Accordingly, the following thermocompression bonding processing can be efficiently performed. Thus, a microstructure apparatus 1 having an excellent hermetic seal reliability can be realized.

In the microstructure apparatus 1 of this embodiment, in order to suppress connection of the metal balls 10 at the step of forming the solder precoat (FIG. 3B), it is desirable that the amount of filler 10 added to that of the mixture of the solder 9 and the filler 10 is 15% or less by weight ratio. Furthermore, in the case where the amount of filler 10 added to 2% or more by weight ratio, the flowability of the solder is lowered, and sufficient thermal resistance of the solder can be obtained. Thus, the problems that the solder crushes and flows during thermocompression bonding can be solved, and the thermal resistance can be improved.

The weight ratio of the filler 10 to the paste 20 is obtained by measuring the density of the paste 20 and measuring the weight ratio of the solder 9 as a main material, and the filler 10.

The weight ratio of the filler 10 to the sealing member 5 after thermocompression bonding can be measured, for example, by shaving the cross section of the sealing member 5, mapping the element distribution of the cross section using a technique, such as wavelength dispersive EPMA, and measuring the weight ratio of the filler 10 in terms of the area of the mapped elements.

There is almost no difference between the weight ratio of the filler 10 obtained from the paste 20 and the weight ratio of the filler 10 obtained from the sealing member 5 after thermocompression bonding.

Furthermore, in order to appropriately lower the flowability of the solder and obtain the effect of suppressing crush of the solder at thermo compression bonding, the modal particle size of the filler 10 is preferably 15 μm or more and less than 30 μm. If the modal particle size is 15 μm or more, the filler 10 can receive a load applied to the first substrate 2 and, thus, crush of the solder 9 can be suppressed. Furthermore, if the modal particle size is less than 30 μm, the flowability of the solder 9 around the filler 10 is maintained, and, thus, formation of bulky voids around the filler 10 is suppressed, and a desired hermetic seal reliability can be satisfactorily achieved. Furthermore, if the modal particle size is 15 μm or more and less than 30 μm, mounting failure during thermocompression bonding caused by the inhibition of deformation of the solder at thermocompression bonding the filler 10 can be suppressed. The modal particle size refers to the maximum value of a particle size spectrum obtained based on the particle size measured by a method such as a laser diffraction and scattering method or a dynamic optical scattering method and the mixing ratio of the particle sizes.

In the case where the solder material is an Sn-based solder, formation of non-spherical or other abnormal shapes of voids in the solder caused by too grown intermetallic compound layer 24 can be suppressed, and the sealing member 5 can be formed in a state where the hermetic seal reliability is secured. The material of the solder is preferably a lead free solder, such as a SnAg-based solder or an SnAgCu-based solder, but the above-described effect can be obtained even if an SnP-based solder is used.

Furthermore, in the above-described manufacturing method, the solder is thermocompression-bonded by pressure and heat at thermocompression bonding, and, thus, even if there are voids in the solder, the applied pressure changes the shape of the solder, and mounting can be performed with voids crushing. Furthermore, since the metal balls 10 are not connected to each other with the intermetallic compound 24 at thermocompression bonding step, the solder can appropriately flow when a pressure is applied. Furthermore, since the melting point of the intermetallic compound formed by the above-described manufacturing method is higher than that of Sn, the thermal resistance of the sealing member 5 is improved, and a secondary mounting can be performed at a higher temperature. That is to say, a solder having a higher melting point can be used as a solder when mounting the microstructure apparatus 1 on another substrate such as a printing substrate.

The conductive member 8 may be made of the same material as the sealing member 5. In the case where the conductive member 8 is made of the same material as the sealing member 5, they can be produced through the same process, and the number of manufacturing steps of the microstructure apparatus 1 is reduced. Thus, products can be stably supplied at low cost. Furthermore, since the conductive member 8 and the sealing member 5 are produced through the same process, residual stress caused by mounting can be alleviated. Furthermore, since the height of the conductive connecting member 8 is the same as that of the sealing member 5, stress applied to the microstructure 4 is reduced, and thus the reliability of the microstructure 4 can be secured. Furthermore, in the case where a reference potential is supplied to the sealing member 5 and the conductive connecting member 8 is used as a signal conductor, impedance matching can be easily performed because the members have the same electrical conductivity, and a mounting structure of the microstructure apparatus 1 with a smaller amount of high-frequency loss can be realized.

In this embodiment, the pad 2b that forms a conductor pattern is disposed on the surface 2a of the first substrate 2, and the pad 3b that forms a conductor pattern is disposed on the surface 3a of the second substrate 3, but it is not limited in this configuration, and a pad that forms a conductor pattern may be disposed on only one of the surface 2a of the first substrate 2 and the surface 3a of the second substrate 3.

### Second Embodiment

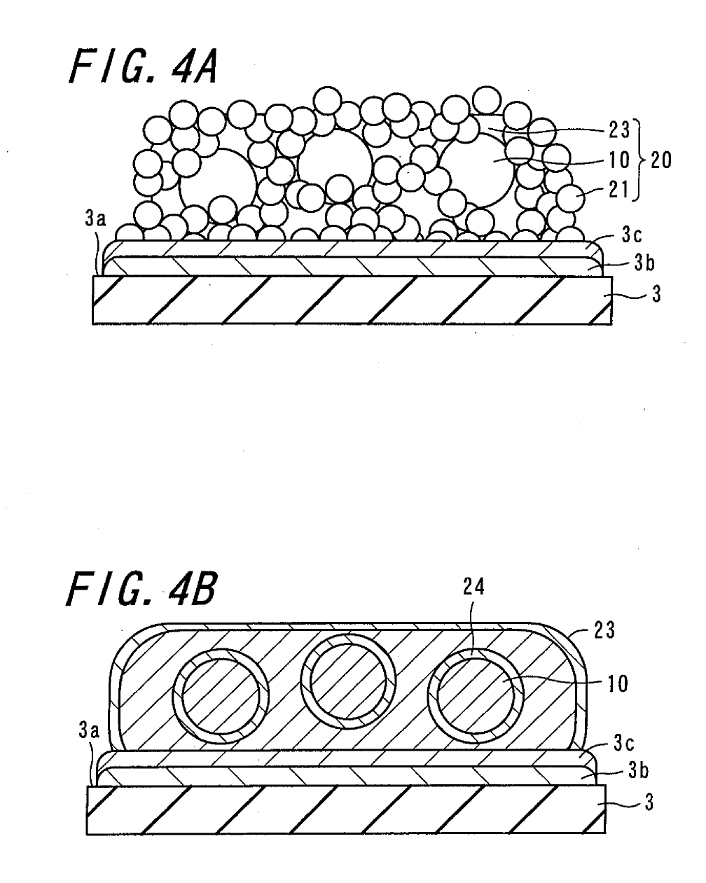

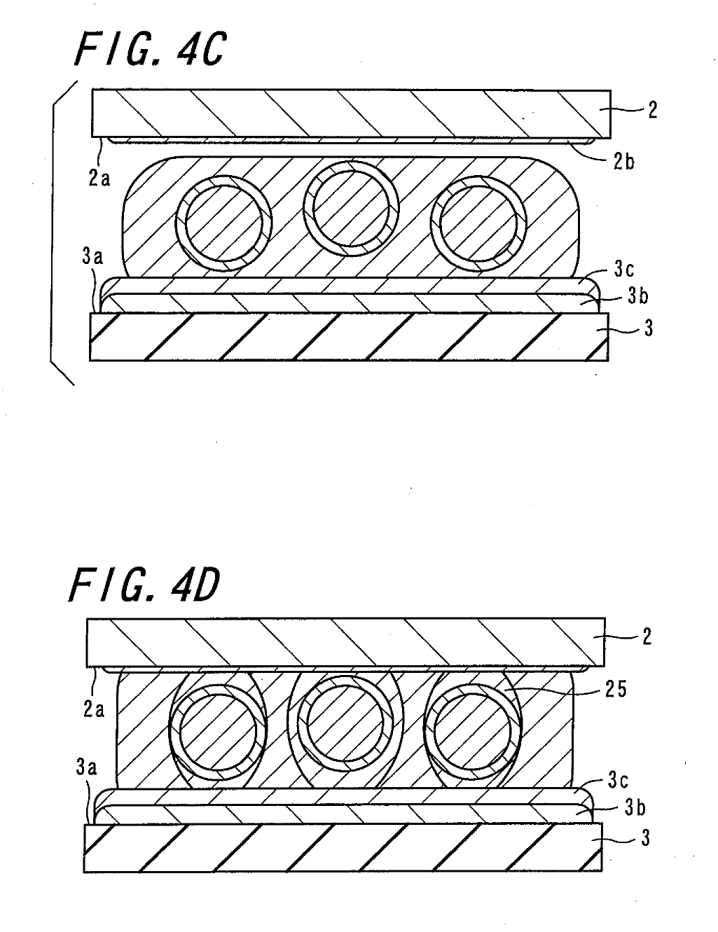

Next, the microstructure apparatus according to a second embodiment of the invention is described. The microstructure apparatus according to this embodiment is different from the microstructure according to the first embodiment in the way that the first substrate 2 and the second substrate 3 are bonded with the sealing member 5. Hereinafter, this way of bonding is described with reference to FIGS. 4A to 4D. The cross-sectional view in FIG. 1 and the plan view in FIG. 2 are also applicable to the microstructure apparatus according to this embodiment.

FIGS. 4A to 4D are views for illustrating a method for forming the sealing member 5 in the processing that manufactures the microstructure apparatus according to this embodiment. As shown in FIGS. 4A to 4D, in the microstructure apparatus according to this embodiment, a metal layer 3c is further disposed on the surface of the pad 3b that is disposed on the surface 3a of the second substrate 3. The pad 3b is made of a Cu or Ag film formed, fur example, by a thick film method, and the metal layer 3c is formed, for example, by coating the surface of the pad 3b sequentially with Ni and Pd by a plating method. In this embodiment, the conductor pattern includes the pad 3b and the metal layer 3c.

First, as shown in FIG. 4A, the paste 20 that is to be the sealing member 5 is applied to the second substrate 3. This processing is the same as that in the first embodiment in FIG. 3A. In order to secure the wettability with the solder, a pad 3b whose surface is provided with a Pd film is disposed on the second substrate 3. The paste 20 includes, for example, solder balls 21 made of an Sn-based solder, filler 10 made of copper balls, and the flux 23. The ratio of the weight of the Pd metal layer to the weight of the balls made of an Sn based solder is preferably 1/300 or more and 1/100 or less, and the ratio of the weight of the Ni metal layer to the weight of the balls made of an Sn-based solder is preferably 1/30 or more and 1/10 or less.

Next, as shown in FIG. 4B, a solder precoat is formed on the second substrate 3 by performing heat treatment, and melting the solder balls 21. This processing is also the same as that in the first embodiment in FIG. 3B, and, thus, a description thereof has been omitted.

Next, as shown in FIG. 4C, the first substrate 2 is provided. The first substrate 2 is a substrate mainly made of silicon on which the microstructure 4, such as an MEMS, is mounted. This processing is also the same as that in the first embodiment in FIG. 3B. In order to secure the wettability with the Sn solder, a pad 2b made of a metal is disposed on the surface of the first substrate 2 that is brought into contact with the solder precoat. In this case, a metal layer may be disposed on the surface of the pad 2b as in the case of the pad 3b. In this case, the conductor pattern includes the pad 2b and the metal layer.

Next, as shown in FIG. 4D, the first substrate 2 and the second substrate 3 are thermocompression-bonded. The pressure range at thermocompression bonding is preferably approximately 0.1 to 10 MPa. The temperature range is set to a temperature higher than that when forming the solder precoat shown in FIG. 4B, and it is typically desirable that the temperature range is 250° C. or higher. In this processing, Pd is diffused from the pad 3b into the paste, and an SnCuPd compound 25 is produced and grown sufficiently. Thus, the first substrate 2 and the second substrate 3 are firmly bonded with the SnCuPd compound 25.

In particular, according to the microstructure apparatus of this embodiment, since the metal layer 3c made of an Ni film and a Pd film is disposed on the surface of the pad 3b, reaction with the Pd film disposed on the pad 3b, Sn in the solder and Cu in the filler forms the SnCuPd compound. The wettability of the SnCuPd compound with the solder is better than that of a SnCu compound, and a high hermetic seal reliability can be realized. In this case, it is desirable that the Pd plate is uniformly formed on the surface so that Ni in the base plate does not bind to Cu, that the thickness of the Ni plate is 0.5 to 1 μm, and that the thickness of the Pd plate is 0.01 to 0.3 μm. In the case where these conditions are satisfied, passing of Ni from the base plate through the Pd barrier plate is effectively suppressed, and a desired SnCuPd alloy can be formed. Furthermore, in the case where the Ni plate is 0.5 μm or more and the Pd plate is 0.3 μm or less, formation of an SnPd-based alloy having a poor wettability with Sn is effectively suppressed, and the hermetic seal reliability can be sufficiently maintained.

Furthermore, in order to further reduce collapse of the solder under pressure, the thickness of the Ni plate in the metal layer 3c is increased. Accordingly, formation of an SnCuNi-based alloy is facilitated together with the formation of the SnCuPd-based alloy, and an SnCuNi-based alloy that tends to be formed in one direction in the Sn-based solder is formed. In this case, it is desirable that the thickness of the Ni plate is approximately 1 to 5 μm. With this configuration, in particular, in the case where the second substrate 3 is made of a low temperature co-fired ceramic (LTCC), where the pad 3b is made of a Cu based film formed by a thick film method, and where this Cu based film is coated with Ni and Pd plate layers, formation of so-called KirKendall voids can be suppressed, which is the phenomenon that Cu forming the pad 3b is in solid solution in the Sn-based solder and voids are formed in the film of the pad 3b. Thus, it is possible to sufficiently facilitate formation of an alloy layer of Cu balls in the solder, a Sn-based solder, and Ni, while satisfying an original purpose of the Ni plate, which is to maintain the long-term reliability of the bonded portion and to suppress an increase in the electrical conductivity.

According to the microstructure of this embodiment, since the first substrate 2 and the second substrate 3 are connected with an SnCuPd-based alloy, crystal growth of hexagonal crystals is facilitated more than that of hexagonal crystals in the case of an SnCu-based alloy when the crystals grow, and as a result, the crystals grow in one direction. Thus, large crystals are formed between the surface 2a of the first substrate 2 and the surface 3a of the second substrate 3. Accordingly, crush of the solder can be more effectively suppressed, and a microstructure 4 having a larger aspect ratio, that is, having a greater height can be effectively hermetically sealed.

Furthermore, an SnCuPd-based alloy has a better wettability with the Sn solder than that of other alloys, and can be uniformly boneded with the Sn solder. Thus, a high hermetic seal reliability is obtained.

The thickness of each metal layer is measured by cutting the sealing member 5 in a direction that is perpendicular to the surface of the first substrate 2 or the second substrate 3, and measuring the thickness of each metal layer in the cross section by scanning electron microscopy (SEM).

In this specification, the description is based on the configuration in which the Ni layer and the Pd layer are formed by a plating method, but these layers may be formed by a thin film technique or the like, and the process may be changed appropriately, as long as the composition and the thickness do not negatively affect the formation of the alloy layer.

Furthermore, the degree of formation of the alloy layer can be controlled by controlling the thickness of the metal layer 3c disposed on the surface of the pad 3b, the temperature in the treatment of FIG. 4D, and the like. For example, in the case where the thickness of the metal layer 3c is increased and the temperature in the treatment of FIG. 4D is increased, formation of the alloy layer is facilitated. Conversely, a SnCu compound and an SnCuPd compound can be simultaneously formed, and the composition ratio can toe controlled, by controlling the thickness of the metal layer 3c and the treatment temperature.

Furthermore, the alloy layer is not limited to a SnCuPd based alloy, and may be, for example, a SnCuAu-based alloy layer. In this case, the alloy layer preferably has a better wettability with the Sn-based solder than a SnCu-based solder. Furthermore, in order to increase binding to SnCu, it is desirable that the Ni plate is a P—Ni plate in which diffusion into Sn is comparatively facilitated. On the other hand, in order to reduce binding to SnCu, it is desirable that the Ni plate is a plate in which diffusion into Sn is not comparatively facilitated, such as B—Ni subjected to sintering treatment. In these cases, the desired characteristics regarding the properties that maintain the height of the solder and the wettability with the Sn solder can be satisfactorily achieved.

Furthermore, the pad 3b is made of a Cu or Ag film formed, for example, by a thick film method, and the metal layer 3c may be formed by coating the surface of the pad 3b sequentially, for example, with Ni and Au by a thin film method or a plating method. In this case, in order to prevent Sn from eroding the film of the pad 3b, it is desirable that the thickness of Ni is 1 μm or more, and the thickness of Au is 0.01 to 0.05 μm. Furthermore, a thin film made of Ti or W may be formed as the pad 3b, and the surface may be sequentially coated with a barrier layer made of Pt, Pd or the like and Au as the metal layer 3c. For example, in the case where the first substrate 2 is made of silicon and the second substrate is made of ceramic, a conductor pattern that includes a Ti thin film, and a Pt film and an Au film sequentially formed on the thin film may be formed on the first substrate 2, and a conductor pattern that includes a Cu film formed by a thick film method, and an Ni film and an Au film sequentially formed on the Cu film may be formed on the second substrate 3. It is not limited to this configuration. For example, a Cr layer may be used instead of the Ni layer, and an Ag layer or the like may be used instead of the Pt layer. The configuration can be changed as appropriate within a range not departing from the gist of the invention. Examples of the metal compound that bonds the first substrate 2 and the second substrate 3 include a SnCuNi based alloy, a SnCuAu-based alloy, and the like. In this case, a conductor pattern that has a metal layer made of Ni or Au as the outermost layer may be formed on at least one of the first substrate 2 and the second substrate 3. Furthermore, in this case, the ratio of the weight of the outermost metal layer to the weight of the balls made of an Sn-based solder is preferably 1/30 or more and 1/10 or less in the case where the outermost metal layer is made of Ni, and 1/300 or more and 1/100 or less in the case where the outermost metal layer is made of Au.

In this embodiment, the pad 2b that forms a conductor pattern is disposed on the surface 2a of the first substrate 2, and the pad 3b and the metal layer 3c that form a conductor pattern are arranged on the surface 3a of the second substrate 3, but it is not limited to this configuration, and a pad, or a pad and a metal layer, that form a conductor pattern may be arranged on only one of the surface 2a of the first substrate 2 and the surface 3a of the second substrate 3.

In the two foregoing embodiments, fillers in the solder may not be coupled. That is to say, fillers may be in contact with each other, or may be apart from each other, in a plan view thereof. Preferably, in a plan view thereof, fillers may be apart from each other, and each filler may be enclosed by the solder. Furthermore, in the case where fillers are separately present in the solder, that is, fillers are dotted throughout the solder, the flowability of the entire solder is more effectively suppressed, and crush of the material of the solder can be suppressed.

Furthermore, in the description above, the solder used was an Sn-based solder, but the solder may be other types of solders, and may be a brazing metal having a melting point of higher than 450 degrees.

The case that the microstructure apparatus 1 is individually manufactured is described above, but a manufacturing method comprising providing a so called water-scale package in which a first mother substrate having aligned first substrates 2 with microstructures 4 are bonded to a second mother substrate having aligned second substrates 3, sealing the microstructures 4, and then, dicing it to divide into each microstructure apparatus 1, may be applied. Also in the case where a plurality of microstructure apparatuses 1 are produced at a time in this manner, packaging can be performed while suppressing contamination of the microstructures 4 with dicing dust.

The invention may be embodied in other specific forms without departing from the spirit or essential characteristics thereof. The present embodiments are therefore to be considered in all respects as illustrative and not restrictive, the scope of the invention being indicated by the appended claims rather than by the foregoing description and all changes which come within the meaning and the range of equivalency of the claims are therefore intended to be embraced therein.

1. A microstructure apparatus comprising:
a first substrate having a surface on which a microstructure is disposed;
a second substrate having a surface opposing the microstructure; and
a sealing member that bonds the opposing surfaces of the first substrate and the second substrate and that encloses and seals the microstructure,
the sealing member comprising a brazing metal containing a filler.

2. The microstructure apparatus of claim 1, wherein the filler comprises metal balls.

3. The microstructure apparatus of claim 2, wherein the metal balls comprise copper, silver, or nickel.

4. The microstructure apparatus of claim 1, wherein the filler comprises balls having a modal particle size of 15 μm to 30 μm.

5. The microstructure apparatus of claim 2, wherein a weight ratio of the filler in the sealing member is 2 to 15%.

6. The microstructure apparatus of claim 1, wherein
the filler comprises balls which are apart from each other, and each of the balls is enclosed by the brazing metal in a plan view thereof.

7. The microstructure apparatus of claim 1, further comprising a conductor pattern disposed in a region on at least one of the surfaces of the first substrate and the surface of the second substrate, the sealing member being bonded to the region, and
the conductor pattern contains nickel, gold, or palladium.

8. The microstructure apparatus of claim 7, wherein a surface of the conductor pattern is plated with nickel, gold or palladium.

9. The microstructure apparatus of claim 8, wherein the brazing metal comprises an Sn-based brazing metal containing the fillers including copper balls, and
The copper balls are connected to each other with a compound comprising an SnCuNi-based alloy, an SnCuAu-based alloy, or an SnCuPd-based alloy.

10. The microstructure apparatus of claim 8, wherein at least either the first substrate and the filler, or the filler and the second substrate are coupled with a compound comprising an SnCuNi-based alloy, an SnCuAu-based alloy, or an SnCuPd-based alloy.

11. The microstructure apparatus of claim 2, wherein the brazing metal comprises an Sn-based brazing metal,
the metal balls comprise copper, and
a CuSn compound layer comprising Cu₆Sn₅ is on at least one of the boundary between the first substrate and the sealing member and the boundary between the second substrate and the sealing member.

12. The microstructure apparatus of claim 1, wherein the filler comprises resin balls or plastic balls.

13. The microstructure apparatus of claim 1, wherein the brazing metal comprises any one material of SnAg, AnPb, AuSn, and SnAgCu as a main component.

14. The microstructure apparatus of claim 1, further comprising:
an electrode that is electrically connected to the microstructure, and that is disposed on the surface of the first substrate;
a wiring conductor that is disposed on the surface and in an internal portion of the second substrate, and that has an end extended to the surface of the second substrate opposing the first substrate; and
a conductive member that connects the electrodes and the end of the wiring conductor,
wherein the conductive member comprises the same material as the sealing member.

15-23. (canceled)
